(19) United States
(12) Patent Application Publication
(10) Pub. No.: US 2025/0204211 A1
(43) Pub. Date: Jun. 19, 2025

(54) DISPLAY DEVICE

(71) Applicant: Samsung Display Co., Ltd., Yongin-Si (KR)

(72) Inventors: Yong Il KIM, Yongin-si (KR); Wan Sang KIM, Yongin-si (KR); Byoung Kyoo PARK, Yongin-si (KR); Wee Joon JEONG, Yongin-si (KR); Jang Un CHOI, Yongin-si (KR)

(21) Appl. No.: 18/774,931

(22) Filed: Jul. 17, 2024

(30) Foreign Application Priority Data
Dec. 18, 2023 (KR) 10-2023-0184111

(51) Int. Cl. H10K 59/80

(52) U.S. Cl. CPC H10K 59/872

(57) ABSTRACT

The present disclosure relates to a display device, and more particularly, to a display device that offers a slim structure and reduced manufacturing costs. In one aspect, what is presented is a display device comprising: a display panel and a vapor chamber, wherein the vapor chamber surrounds a side surface of the display panel.

This application claims the benefit of Korean Patent Application No. 10-2023-0184111 filed on Dec. 18, 2023 in the Korean Intellectual Property Office, the disclosure of which is incorporated herein in its entirety by reference.

### BACKGROUND

### 1. Field

The present disclosure relates to a display device, and more particularly, to a display device with a slim structure that may be produced at a reduced cost.

### 2. Description of the Related Art

Organic light emitting diode displays have self-luminous properties and, unlike liquid crystal displays, do not require a separate light source. There being no need to include a light source results in reduced thickness and weight compared to liquid crystal displays. Due to these desirable qualities, organic light emitting diode displays are drawing attention as next-generation displays for televisions, monitors, and portable electronic devices due to their high-quality characteristics such as low power consumption, high luminance, and high response speed.

### SUMMARY

Aspects of the present disclosure provide a display device that offers a slim structure and reduced manufacturing costs.

According to an embodiment of the disclosure, a display device includes a display panel and a vapor chamber, wherein the vapor chamber surrounds a side surface of the display panel.

In an embodiment, the vapor chamber may have a sidewall surrounding the side surface of the display panel.

In an embodiment, the sidewall may be integrally formed with the vapor chamber.

In an embodiment, the display panel may include a plurality of side surfaces, and the sidewall comprises a plurality of sidewalls facing the side surfaces.

In an embodiment, at least one of the sidewalls may contact a side surface of the display panel.

In an embodiment, the vapor chamber may include: a first plate; a second plate between the first plate and the display panel; an extension portion extending from an edge of the second plate; and a sidewall disposed on the extension portion and surrounding the side surface of the display panel.

In an embodiment, the second plate, the extension portion, and the sidewall may be integrally formed.

In an embodiment, a first flange may be connected to an edge of the first plate; and a second flange may be connected to the first flange and disposed on a portion of the second plate that is across the extension portion from the sidewall.

In an embodiment, the first plate may include a concave portion recessed toward the second plate.

In an embodiment, the vapor chamber may include: a first plate; a second plate between the first plate and the display panel; an extension portion extending from an edge of the first plate; and a sidewall disposed on the extension portion and surrounding the side surface of the display panel.

In an embodiment, the first plate, the extension portion, and the sidewall are integrally formed.

In an embodiment, a second flange may be connected to an edge of the first plate; and a first flange may be bonded to the second plate and disposed between the second flange and the extension portion.

In an embodiment, the second plate may include a concave portion recessed toward the first plate.

An embodiment may include a front cover on the display panel.

In an embodiment, at least a portion of the vapor chamber may surround a side surface of the front cover.

In an embodiment, the vapor chamber may include a sidewall surrounding the side surface of the display panel and the side surface of the front cover.

According to an embodiment of the disclosure, a display device includes a display panel, a vapor chamber having a bottom plate connected to an outward-facing surface; and a side cover surrounding a side surface of the display panel and the outward-facing surface of the vapor chamber.

In an embodiment, the side cover may include a support portion extending from an inner surface of the side cover.

In an embodiment, the support portion may be disposed below the vapor chamber.

In an embodiment, the support portion may be disposed between the vapor chamber and the display panel.

An embodiment may further include a circuit member connected to the display panel, wherein the support portion has a through hole through which the circuit member extends.

The effects of the present disclosure are not limited to the above-described effects and other effects which are not described herein will become apparent to those skilled in the art from the following description.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to an embodiment;

FIG. 2 is a plan view of the display device according to the embodiment;

FIG. 3 is a circuit diagram of the display device according to the embodiment;

FIG. 4 is a cross-sectional view of the display device according to the embodiment;

FIG. 5 is a perspective view of a portion of a vapor chamber according to an embodiment;

FIG. 6 is an enlarged view of a portion of the vapor chamber according to the embodiment;

FIG. 7 is a cross-sectional view of a display device according to an embodiment;

FIG. 8 is a perspective view of a portion of a vapor chamber according to an embodiment;

FIG. 9 is an enlarged view of a portion of the vapor chamber according to the embodiment of FIG. 8;

FIG. 10 is a cross-sectional view of a display device according to an embodiment;

FIG. 11 is a cross-sectional view of a display device according to an embodiment;

FIG. 12 is a cross-sectional view of a display device according to an embodiment;

FIG. 13 is a cross-sectional view of a display device according to an embodiment; and

FIG. 14 is a cross-sectional view of a display device according to an embodiment.

### DETAILED DESCRIPTION

Advantages and features of the present disclosure and methods to achieve them will become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Ordinal terms such as first, second, etc. are used to distinguish between elements, and thus these terms are not necessarily intended to indicate any order or prioritization of such elements. These terms are used to merely distinguish one element from another. Accordingly, as used herein, a first element may be a second element within the technical scope of the present disclosure.

Features of various exemplary embodiments of the present disclosure may be combined partially or totally. As will be clearly appreciated by those skilled in the art, technically various interactions and operations are possible. Various exemplary embodiments can be practiced individually or in combination.

Hereinafter, exemplary embodiments of the present disclosure will be described with reference to the accompanying drawings.

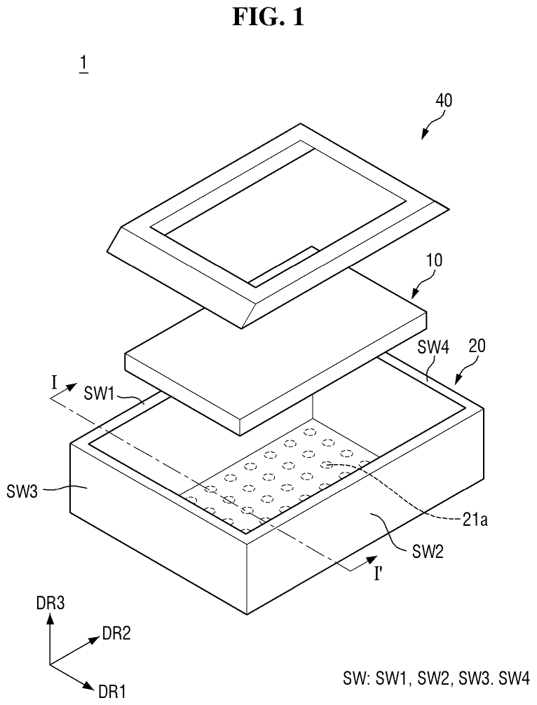

FIG. 1 is an exploded perspective view of a display device 1 according to an embodiment.

Referring to FIG. 1, the display device 1 according to the embodiment may be applied to smartphones, mobile phones, tablet personal computers (PCs), personal digital assistants (PDAs), portable multimedia players (PMPs), televisions, game consoles, wristwatch-type electronic devices, head mounted displays, monitors of PCs, laptop computers, car navigation systems, car dashboards, digital cameras, camcorders, outdoor billboards, electronic display boards, medical devices, examination devices, various home appliances such as refrigerators and washing machines, or Internet of things (IoT) devices. In the present specification, a television will be described as an example of the display device 1. The television may have high resolution or ultra-high resolution such as HD, UHD, 4K, or 8K.

In addition, the display device 1 according to the embodiment may be variously classified according to a display method. For example, the display device 1 may be classified as an organic light emitting diode display device, an inorganic electroluminescent (EL) display device, a quantum dot light emitting display device (QED), a micro-light emitting diode display device, a nano-light emitting diode display device, a plasma display panel (PDP), a field emission display (FED) device, a cathode ray tube (CRT) display device, a liquid crystal display (LCD) device, or an electrophoretic display (EPD) device. An organic light emitting diode display device will be described below as an example of the display device 1. Unless a special distinction is required, the organic light emitting diode display device applied to embodiments will be simply shortened to a display device. However, the embodiments are not limited to the organic light emitting diode display device, and other display devices listed above or known in the art can also be applied within the scope sharing the technical spirit.

The display device 1 may include a vapor chamber 20, a display panel 10, and a front cover 40. The vapor chamber 20, the display panel 10, and the front cover 40 may be disposed, for example, along a third direction DR3. The display panel 10 may be disposed between the vapor chamber 20 and the front cover 40.

The display panel 10 may be a self-luminous display panel 10. The display panel 10 as a self-luminous display panel 10 may be an organic light emitting display panel 10. However, the present disclosure is not limited thereto, and other types of display panels 10 such as a liquid crystal display panel, a quantum dot organic light emitting display panel 10, a quantum dot liquid crystal display panel, a quantum nano-light emitting display panel 10, and a micro-light emitting diode display panel may also be applied.

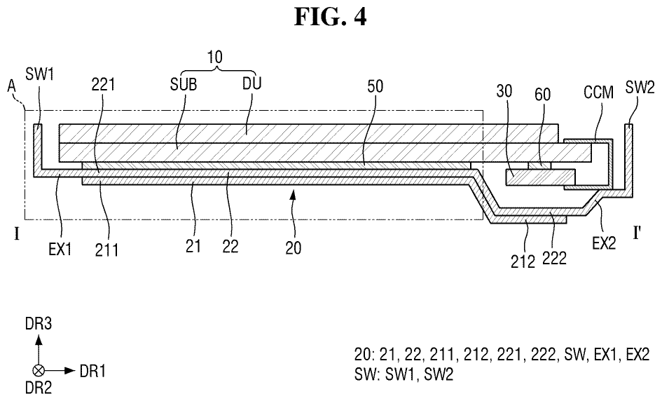

The display panel 10 may include a substrate SUB (see FIG. 4) and a display layer DU (see FIG. 4) disposed on the substrate SUB. The detailed structure of the display panel 10 will be described later with reference to FIG. 4 and the like.

The vapor chamber 20 may transfer the heat generated from the display panel 10 and a driving board 30 (see FIG. 4) to another space inside the display device 1 or to the outside. For example, the vapor chamber 20 may dissipate the heat generated from the display panel 10 and the driving board 30 to the internal space of the front cover 40 or to the outside of the display device 1.

At least a portion of the vapor chamber 20 may surround the display panel 10. For example, at least a portion of the vapor chamber 20 may surround the side surfaces of the display panel 10. Therefore, the vapor chamber 20 may protect the side surfaces of the display panel 10. According to an embodiment, the vapor chamber 20 may include a bottom plate and sidewalls SW surrounding the side surfaces of the display panel 10. The sidewalls SW may include a first sidewall SW1, a second sidewall SW2, a third sidewall SW3, and a fourth sidewall SW4 disposed at four edges of the vapor chamber 20, respectively. The first through fourth sidewalls SW1 through SW4 may be integrally formed with the vapor chamber 20. As in the example illustrated in FIG. 1, when the display panel 10 has a quadrangular shape including four side surfaces (e.g., a first side surface, a second side surface, a third side surface, and a fourth side surface), the sidewalls SW1 through SW4 of the vapor chamber 20 may be placed to face the side surfaces of the display panel 10. For example, the first sidewall SW1 may face the first side surface of the display panel 10, the second sidewall SW2 may face the second side surface of the display panel 10, the third sidewall SW3 may face the third side surface of the display panel 10, and the fourth sidewall SW4 may face the fourth side surface of the display panel 10.

According to an embodiment, the first through fourth sidewalls SW1 through SW4 may be integrally formed.

According to an embodiment, the first through fourth sidewalls SW1 through SW4 and the vapor chamber 20 may include metal such as aluminum.

The display device 1 including a heat dissipation member such as the vapor chamber 20 can quickly disperse or dissipate heat generated from the driving board 30.

The front cover 40 and the vapor chamber 20 may surround the display panel 10 and the driving board 30. The front cover 40 may protect the display panel 10 and the driving board 30 from external shock.

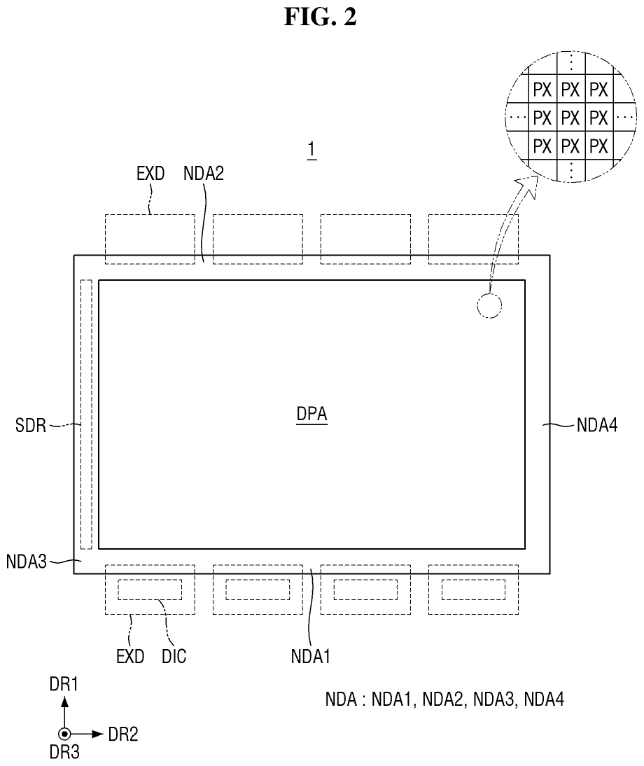

The front cover 40 may include a highly transparent material to allow light emitted from the display panel 10 to pass therethrough. For example, the front cover 40 may include polymer resin such as polyimide or glass. In an embodiment, the front cover 40 may include an opening which is open in an area overlapping a display area DPA (see FIG. 2).

Each of the vapor chamber 20, the display panel 10, and the front cover 40 may include long sides extending in a first direction DR1 and short sides extending in a second direction DR2.

At least a portion of the vapor chamber 20 may surround side surfaces of the front cover 40. For example, the sidewalls SW of the vapor chamber 20 may surround the side surfaces of the front cover 40. As in the example illustrated in FIG. 1, when the front cover 40 has a quadrangular shape including four side surfaces (e.g., a first side surface, a second side surface, a third side surface, and a fourth side surface), the sidewalls SW1 through SW4 of the vapor chamber 20 may be placed to face the side surfaces of the front cover 40. For example, the first sidewall SW1 may face the first side surface of the front cover 40, the second sidewall SW2 may face the second side surface of the front cover 40, the third sidewall SW3 may face the third side surface of the front cover 40, and the fourth sidewall SW4 may face the fourth side surface of the front cover 40.

The front cover 40 is optional.

According to an embodiment, the vapor chamber 20 may perform the function of covers (e.g., a side cover and a rear cover) of the display device 1 along with a heat dissipation function. Therefore, a bezel size of the display device 1 can be reduced, enabling a slim structure. In addition, according to an embodiment, since the rear cover and the side cover are not required, manufacturing costs of the display device 1 can be reduced. In addition, since the vapor chamber 20 is exposed to the outside without being covered by the rear cover, the heat dissipation effect of the vapor chamber 20 can be improved.

FIG. 2 is a plan view of the display device 1 according to the embodiment.

Referring to FIG. 2, the display device 1 according to the embodiment may have a quadrangular shape in plan view. For example, the display device 1 may have a rectangular shape, but the present disclosure is not limited thereto.

In some embodiments, when the display device 1 is a television, its long sides extend in the second direction. However, the present disclosure is not limited thereto, and the long sides may also extend in the first direction, or the display device 1 may be rotatably installed so that the long sides can be variably extend in the first or second direction.

The display device 1 may include the display area DPA and a non-display area NDA. The display area DPA may be an active area in which an image is displayed. The display area DPA may have a rectangular shape similar to the overall shape of the display device 1 in plan view, but the present disclosure is not limited thereto.

The display area DPA may include a plurality of pixels PX. The pixels PX may be arranged in a matrix direction. Each of the pixels PX may be rectangular or square in plan view. However, the present disclosure is not limited thereto, and each of the pixels PX may also have a rhombus shape having each side inclined with respect to a side of the display device 1. The pixels PX may include pixels PX which provide light of different colors (or wavelengths). For example, the pixels PX may include, but are not limited to, red pixels providing red light, green pixels PX providing green light, and blue pixels providing blue light. The color pixels PX may be alternately arranged in a stripe or pentile type.

The non-display area NDA may be disposed around the display area DPA. The non-display area NDA may form the bezel of the display device 1. The non-display area NDA may entirely or partially surround the display area DPA.

In some embodiments, the display area DPA may have a rectangular shape, and the non-display area NDA may be disposed adjacent to four sides of the display area DPA. For example, the non-display area NDA may include a first non-display area NDA1 disposed adjacent to a first long side (which extends in the second direction DR2 and is adjacent to driving chips DIC in FIG. 2) of the display device 1, a second non-display area NDA2 disposed adjacent to a second long side (which extends in the second direction DR2 parallel to the first long side in FIG. 2), a third non-display area NDA3 disposed adjacent to a first short side (which extends in the first direction DR1 and is adjacent to a scan driver SDR in FIG. 2), and a fourth non-display area NDA4 disposed adjacent to a second short side (which extends in the first direction DR1 parallel to the first short side in FIG. 2).

Driving circuits or driving elements for driving the display area DPA may be disposed in the non-display area NDA. For example, a pad portion may be provided on the substrate SUB of the display panel 10 in the first non-display area NDA1 and the second non-display area NDA2, and external devices EXD may be mounted on pad electrodes of the pad portion. Each of the external devices EXD may include a circuit member CCM (see FIG. 4) which will be described later. Examples of the external devices EXD may include connection films, printed circuit boards, driving chips DIC, connectors, and wiring connection films. For another example, the scan driver SDR formed directly on the substrate SUB of the display panel 10 may be disposed in the third non-display area NDA3.

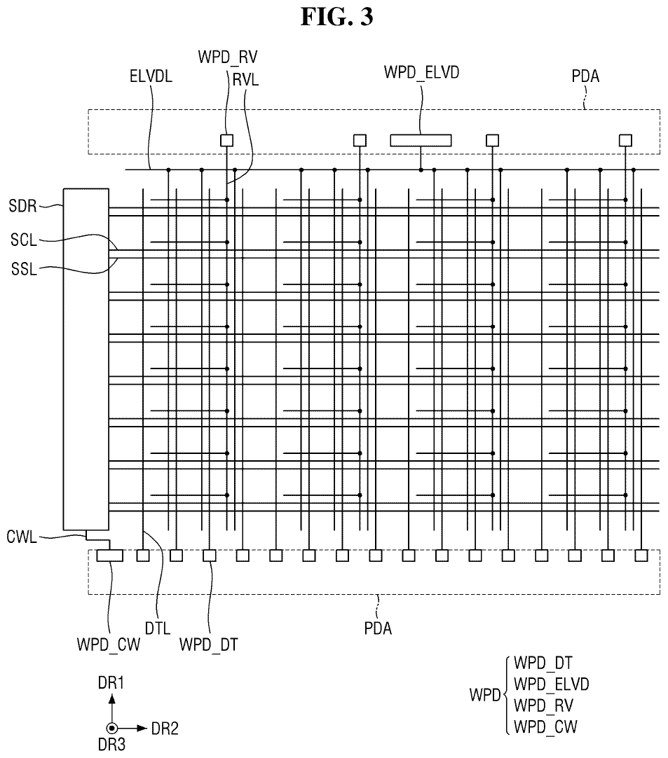

FIG. 3 is a circuit diagram of the display device 1 according to the embodiment.

Referring to FIG. 3, a plurality of lines may be disposed on the substrate SUB of the display device 1. The lines may include scan lines SCL, sensing signal lines SSL, data lines DTL, reference voltage lines RVL, and a first power line ELVDL.

The scan lines SCL and the sensing signal lines SSL may extend in the second direction DR2. The scan lines SCL and the sensing signal lines SSL may be connected to the scan driver SDR. The scan driver SDR may include a driving circuit composed of circuit layers. The scan driver SDR may be disposed in the third non-display area NDA3. However, the present disclosure is not limited thereto, and the scan driver SDR may also be disposed in the fourth non-display area NDA4 or may also be disposed in both the third non-display area NDA3 and the fourth non-display area NDA4. The scan driver SDR may be connected to a signal connection line CWL, and at least one end of the signal connection line CWL may form a pad WPD_CW in the first non-display area NDA1 and/or the second non-display area NDA2 and thus may be connected to an external device EXD (see FIG. 2).

In the drawing, the first direction DR1 and the second direction DR2 intersect each other. For example, the first direction DR1 and the second direction DR2 may be orthogonal to each other. In addition, the third direction DR3 may be referred to as “a vertical direction” and intersect the first direction DR1 and the second direction DR2; for example, the third direction DR3 may be orthogonal to the first direction DR1 and the second direction DR2. In the present specification, a direction indicated by an arrow of each of the first through third directions DR1 through DR3 may be referred to as one side, and the opposite direction may be referred to as the other side.

The data lines DTL and the reference voltage lines RVL may extend in the first direction DR1 intersecting the second direction DR2. The first power line ELVDL may include a portion extending in the second direction DR2. The first power line ELVDL may further include portions extending in the first direction DR1. The first power line ELVDL may have a mesh structure, but the present disclosure is not limited thereto.

A wiring pad WPD may be disposed on at least one end of each of the data lines DTL, the reference voltage lines RVL, and the first power line ELVDL. Each wiring pad WPD may be disposed in a pad portion PDA of the non-display area NDA. In an embodiment, wiring pads WPD_DT (hereinafter, referred to as ‘data pads’) of the data lines DTL may be disposed in the pad portion PDA of the first non-display area NDA1, and wiring pads WPD_RV (hereinafter, referred to as ‘reference voltage pads’) of the reference voltage lines RVL and a wiring pad WPD_ELVD (hereinafter, referred to as a ‘first power pad’) of the first power line ELVDL may be disposed in the pad portion PDA of the second non-display area NDA2. Alternatively, the data pads WPD_DT, the reference voltage pads WPD_RV, and the first power pad WPD_ELVD may all be disposed in the same area, for example, in the first non-display area NDA1. The external devices EXD (see FIG. 2) may be mounted on the wiring pads WPD as described above. The external devices EXD may be mounted on the wiring pads WPD through anisotropic conductive films, ultrasonic bonding, or the like.

Each pixel PX on the substrate SUB of the display panel 10 may include a pixel driving circuit. The above-described lines may transmit driving signals to each pixel driving circuit while passing through or around each pixel PX. The pixel driving circuit may include a transistor and a capacitor. The number of transistors and capacitors in each pixel driving circuit can be variously changed.

FIG. 4 is a cross-sectional view of the display device 1 according to the embodiment. For example, FIG. 4 may be a cross-sectional view taken along line I-I of FIG. 1.

The vapor chamber 20 may include a first plate 21, a second plate 22, a first flange 211, a second flange 212, a third flange 221, a fourth flange 222, and the sidewalls SW. In FIG. 4, the first sidewall SW1 and the second sidewall SW2 facing each other in the first direction DR1 among the first through fourth sidewalls SW1 through SW4 are illustrated.

The first plate 21, the first flange 211, and the second flange 212 may be integrally formed to make up the bottom plate of the vapor chamber.

The second plate 22, the third flange 221, the fourth flange 222, a first extension portion EX1, a second extension portion EX2, the first sidewall SW1, and the second sidewall SW2 may be integrally formed.

The first plate 21 may have a quadrangular shape in plan view. The first plate 21 may include a stainless steel material with excellent corrosion resistance.

The second plate 22 may have a quadrangular shape in plan view. The second plate 22 may be disposed on the first plate 21 to face the first plate 21 in the third direction DR3. For example, as illustrated in FIG. 4, the second plate 22 may be disposed between the first plate 21 and a first adhesive member 50. The second plate 22 may include the stainless steel material described above.

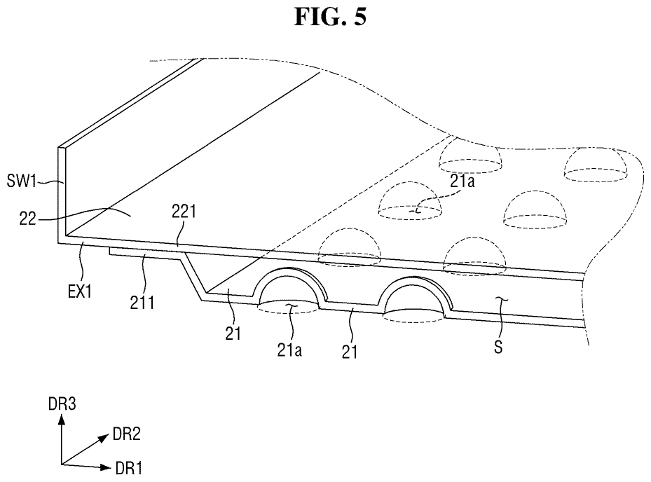

The first plate 21 and the second plate 22 may be placed to interface each other in a plane defined by the first direction DR1 and the second direction DR2. In some embodiments (e.g., FIG. 5), the first plate 21 and the second plate 22 may be spaced apart from each other in the third direction DR3. A space may be provided between the first plate 21 and the second plate 22. A fluid may be disposed in the space between the first plate 21 and the second plate 22. The fluid may be a liquid such as water. Heat generated from the display panel 10 and the driving board 30 may be transferred to the vapor chamber 20 to evaporate the fluid within the vapor chamber 20. For example, the temperature of the fluid may be increased by the heat, and the fluid at the increased temperature may evaporate and condense. As these evaporation and condensation processes are repeated, heat from heat-generating components of the display device 1, such as the display panel 10 and the driving board 30, may be released to the outside.

The first flange 211 may be disposed at an edge of the first plate 21, and the second flange 212 may be disposed at the other edge of the first plate 21. The first flange 211 and the second flange 212 may be integrally formed with the first plate 21. The second flange 212 may be bent into an L shape.

The third flange 221 may be disposed at an edge of the second plate 22, and the fourth flange 222 may be disposed at the other edge of the second plate 22. The third flange 221 and the fourth flange 222 may be integrally formed with the second plate 22. The fourth flange 222 may be bent into an L shape. As each of the fourth flange 222 and the second flange 212 is bent into an L shape, a distance between the display panel 10 and the fourth flange 222 may increase. Therefore, a space in which the driving board 30 can be placed can be secured between the substrate SUB of the display panel 10 and the fourth flange 222.

The first flange 211 of the first plate 21 and the third flange 221 of the second plate 22 may contact each other, and the second flange 212 of the first plate 21 and the fourth flange 222 of the second plate 22 may contact each other. For example, the first flange 211 and the third flange 221 may be bonded to each other through a method such as welding, and the second flange 212 and the fourth flange 222 may be bonded to each other through a method such as welding. The first plate 21 and the second plate 22 may be coupled to each other by the first flange 211, the second flange 212, the third flange 221, and the fourth flange 222. The inside of the vapor chamber 20 may be sealed by the bonding of the first through fourth flanges 211, 212, 221 and 222. In other words, the space between the first plate 21 and the second plate 22 may be sealed by the bonding of the first through fourth flanges 211, 212, 221 and 222.

The first extension portion EX1 may extend from the third flange 221. For example, as illustrated in FIG. 4, the first extension portion EX1 may extend from the third flange 221 along a reverse direction (hereinafter, referred to as “a first reverse direction”) of the first direction DR1.

The second extension portion EX2 may extend from the fourth flange 222. For example, as illustrated in FIG. 4, the second extension portion EX2 may extend from the fourth flange 222 along the first direction DR1. The second extension portion EX2 may be bent into an L shape. Here, the second extension portion EX2 may be bent to be symmetrical to the fourth flange 222 described above. For example, the second extension portion EX2 and the fourth flange 222 may be symmetrical to each other with respect to the third direction DR3.

The first sidewall SW1 may be disposed on the first extension portion EX1. For example, the first sidewall SW1 may extend (or protrude) from an edge of the first extension portion EX1 along the third direction DR3. An upper surface of the first sidewall SW1 and an upper surface of the display panel 10 (e.g., an upper surface of the display layer DU) may lie on a same plane. For example, supposing that there is a virtual plane that includes the interface between the first plate 21 and the second plate 22, a distance measured orthogonally from the virtual plane is the same to the upper surface of the first sidewall SW1 as to the upper surface of the display layer DU. The first sidewall SW1 may face a side surface of the display panel 10. There may be a space between the first sidewall SW1 and the side surface of the display panel 10 that is closest to the first sidewall SW1.

The second sidewall SW2 may be disposed on the second extension portion EX2. For example, the second sidewall SW2 may extend (or protrude) from an edge of the second extension portion EX2 in the third direction DR3. An upper surface (e.g., an uppermost surface) of the second sidewall SW2 and the upper surface of the display panel 10 (e.g., an uppermost surface of the display layer DU) may lie on the same plane. Due to the fact that the upper surface of the first sidewall SW1 also lies on the same plane as the upper surface of the display layer DU as described above, the upper surface of the second sidewall SW2 and the upper surface of the first sidewall SW1 lie on the same plane. Upper surfaces of the first through fourth sidewalls SW1 through SW4 may lie on the same plane. In other words, distances from the above-described virtual plane to uppermost surfaces of the first through fourth sidewalls SW1 through SW4 in the third direction DR3 may all be the same. The second sidewall SW2 may face a side surface of the display panel 10. There may be a space between the second sidewall SW2 and the side surface of the display panel 10 that is closest to the second sidewall SW2.

In the embodiment of FIG. 4, the sidewall SW include an outward-facing surface of the vapor chamber 20. In plan view, the first through fourth sidewalls SW1 through SW4 may form a closed curve surrounding the driving board 30, the first adhesive member 50, a second adhesive member 60, the circuit member CCM, the substrate SUB, and the display layer DU.

The first adhesive member 50 may be disposed between the vapor chamber 20 and the display panel 10. For example, the first adhesive member 50 may be disposed between the second plate 22 of the vapor chamber 20 and the substrate SUB of the display panel 10. The first adhesive member 50 may bond the second plate 22 and the substrate SUB to each other.

The driving board 30 may be disposed between the vapor chamber 20 and the display panel 10. For example, the driving board 30 may be disposed between the fourth flange 222 of the vapor chamber 20 and the substrate SUB of the display panel 10 at an edge of the display panel 10 (or the substrate SUB).

The driving board 30 and the display panel 10 may be physically and electrically connected to each other through the circuit member CCM. For example, the driving board 30 and the pad portion of the substrate SUB may be physically and electrically connected to each other through the circuit member CCM.

The second adhesive member 60 may be disposed between the driving board 30 and the display panel 10. For example, the second adhesive member 60 may be disposed between the driving board 30 and the substrate SUB of the display panel 10. The second adhesive member 60 may bond the driving board 30 and the substrate SUB to each other.

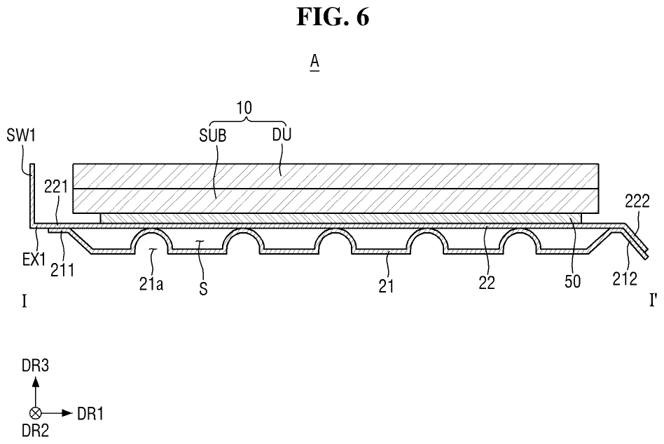

FIG. 5 is a perspective view of a portion of a vapor chamber 20 according to an embodiment. FIG. 6 is an enlarged view of a portion of the vapor chamber 20 according to the embodiment. For example, FIG. 5 may be a perspective view of the vapor chamber 20 of FIG. 4, and FIG. 6 may be an enlarged view of portion A of FIG. 4.

As illustrated in FIGS. 5 and 6, the first plate 21 may further include one or more concave portions 21a (herein also referred to as “recesses”).

The concave portions 21a may have a hemispherical shape as illustrated in FIG. 5. As illustrated in FIGS. 5 and 6, the concave portions 21a may be recessed in the third direction DR3. In other words, the concave portions 21a of the first plate 21 may be recessed toward the second plate 22. For example, as illustrated in FIG. 6, the concave portions 21a of the first plate 21 may have a cross section of a semicircular shape, a parabolic shape, or a convex lens shape. The most recessed portion of each of the concave portions 21a may be disposed adjacent to the second plate 22 or may be in contact with the second plate 22. The concave portions 21a may prevent the first plate 21 and the second plate 22 from being closely attached to each other during a process of forming a space S of the vapor chamber 20 in a vacuum state.

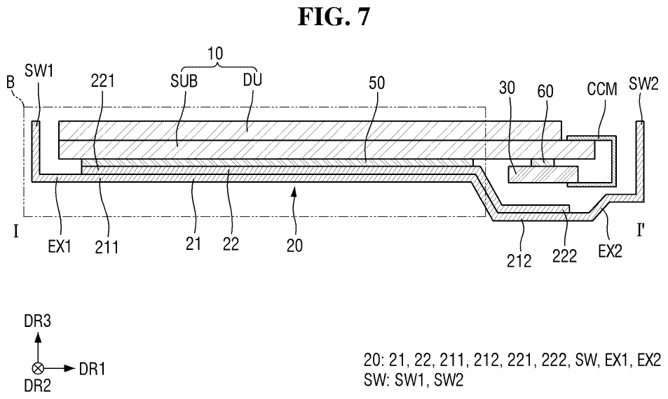

FIG. 7 is a cross-sectional view of a display device 1 according to an embodiment. For example, FIG. 7 may be a cross-sectional view taken along line I-I of FIG. 1.

The display device 1 of FIG. 7 is different from the display device 1 of FIG. 4 described above in the positions of a first extension portion EX1, a second extension portion EX2, a first sidewall SW1, and a second sidewall SW2. Therefore, this difference will be mainly described as follows.

As illustrated in FIG. 7, a vapor chamber 20 may include a first plate 21, a second plate 22, a first flange 211, a second flange 212, a third flange 221, a fourth flange 222, and sidewalls SW. In FIG. 7, the first sidewall SW1 and the second sidewall SW2 facing each other in the first direction DR1 among first through fourth sidewalls SW1 through SW4 are illustrated.

The first plate 21, the first flange 211, the second flange 212, the first extension portion EX1, the second extension portion EX2, the first sidewall SW1, and the second sidewall SW2 may be integrally formed.

The second plate 22, the third flange 221, and the fourth flange 222 may be integrally formed. In the embodiment of FIG. 7, the sidewalls SW1, SW2, SW3, SW4 include an outward-facing surface of the vapor chamber 20.

As illustrated in FIG. 7, the first extension portion EX1 may be connected to the first flange 211, and the second extension portion EX2 may be connected to the second flange 212.

As illustrated in FIG. 7, the first sidewall SW1 may be disposed on the first extension portion EX1 connected to the first flange 211, and the second sidewall SW2 may be disposed on the second extension portion EX2 connected to the second flange 212.

In plan view, the first through fourth sidewalls SW1 through SW4 may form a closed curve surrounding the second plate 22, a driving board 30, a first adhesive member 50, a second adhesive member 60, a circuit member CCM, a substrate SUB, and a display layer DU.

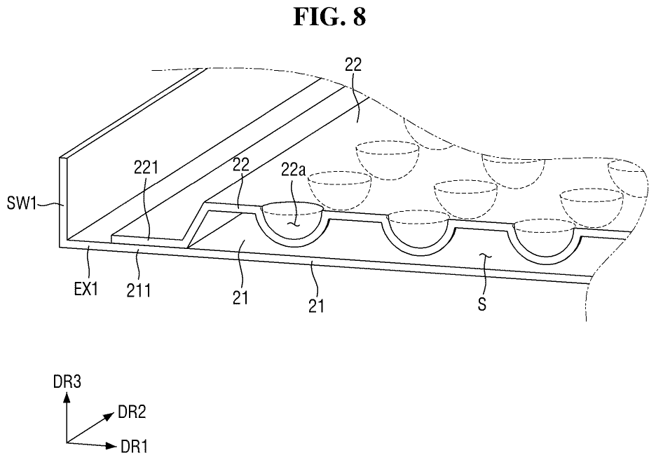

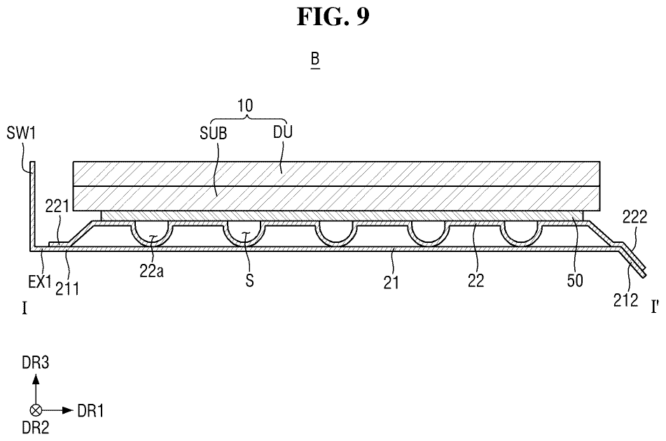

FIG. 8 is a perspective view of a portion of a vapor chamber 20 according to an embodiment. FIG. 9 is an enlarged view of a portion of the vapor chamber 20 according to the embodiment. For example, FIG. 8 may be a perspective view of the vapor chamber 20 of FIG. 7, and FIG. 9 may be an enlarged view of portion B of FIG. 7.

The display device of FIGS. 8 and 9 is different from the display device of FIGS. 5 and 6 described above in the positions of concave portions 22a and sidewalls SW. Therefore, this difference will be mainly described as follows.

As illustrated in FIGS. 8 and 9, a second plate 22 may further include one or more concave portions 22a (herein also referred to as “recesses”).

The concave portions 22a may have a hemispherical shape as illustrated in FIG. 8. As illustrated in FIGS. 8 and 9, the concave portions 22a may be recessed in a reverse direction (hereinafter, referred to as a third reverse direction) of the third direction DR3. In other words, the concave portions 22a of the second plate 22 may be recessed toward a first plate 21. For example, as illustrated in FIG. 9, the concave portions 22a of the second plate 22 may have a cross section of a semicircular shape, a parabolic shape, or a convex lens shape. The most recessed portion of each of the concave portions 22a may be disposed adjacent to the first plate 21 or may be in contact with the first plate 21. The concave portions 22a may prevent the first plate 21 and the second plate 22 from being closely attached to each other during the process of forming a space S of the vapor chamber 20 in a vacuum state.

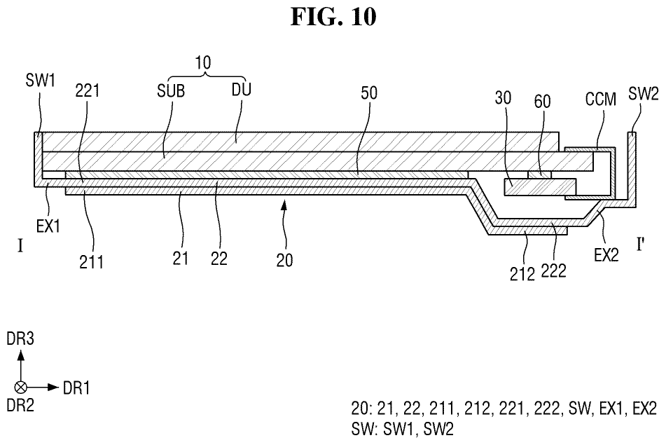

FIG. 10 is a cross-sectional view of a display device 1 according to an embodiment. For example, FIG. 10 may be a cross-sectional view taken along line I-I of FIG. 1.

The display device 1 of FIG. 10 is different from the display device 1 of FIG. 4 described above in that at least one sidewall SW contacts a side surface of a display panel 10. Therefore, this difference will be mainly described as follows.

As illustrated in FIG. 10, a first sidewall SW1 may contact a side surface of the display panel 10. According to an embodiment, the first sidewall SW1 may contact a side surface of a substrate SUB and a side surface of a display layer DU. As illustrated in FIG. 10, the side surfaces of the substrate SUB and the display layer DU may be flush on some sides.

According to an embodiment, the first sidewall SW1, the third sidewall SW3 and the fourth sidewall SW4 may contact side surfaces of the display panel 10 as illustrated in FIG. 10. However, the second sidewall SW2 that is adjacent to the driving board 30 may not contact the side surface of the display panel 10. In the embodiment of FIG. 10, there is a space between the second sidewall SW2 and the display panel 10. Furthermore, in the embodiment of FIG. 10, the side surfaces of the substrate SUB and the display layer DU are not flush.

According to the display device 1 of FIG. 10, a gap between a sidewall SW and the display panel 10 may be minimized. Therefore, the bezel size of the display device 1 can be reduced.

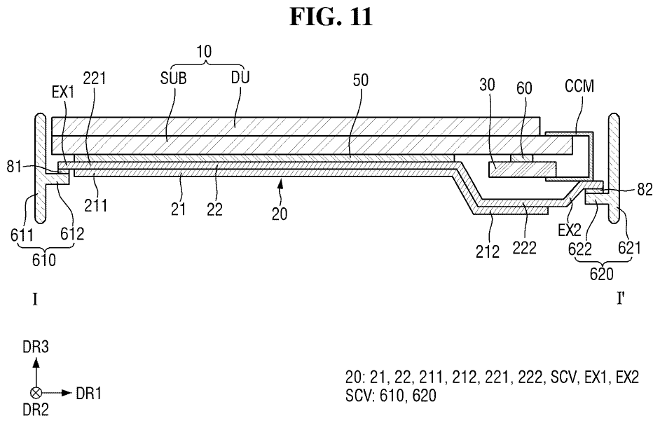

FIG. 11 is a cross-sectional view of a display device according to an embodiment. For example, FIG. 11 may be a cross-sectional view taken along line I-I of FIG. 1.

The display device of FIG. 11 is different from the display device of FIG. 4 described above in that it includes side covers SCV (610, 620) instead of sidewalls SW. In the embodiment of FIG. 11, the outward-facing surface of the vapor chamber 20 are part of the first and second extension portions EX1, EX2 as there are no sidewalls SW. The description of FIG. 11 will focus on this difference.

The side covers SCV may form a closed curve surrounding side surfaces of a display panel 10 in plan view. In an embodiment, the side covers SCV may surround a first plate 21, a second plate 22, a first flange 211, a second flange 212, a third flange 221, a fourth flange 222, a first extension portion EX1, a second extension portion EX2, a driving board 30, a first adhesive member 50, a second adhesive member 60, a third adhesive member 81, a fourth adhesive member 82, a substrate SUB, and a display layer DU.

The side covers SCV may include a first side cover 610 and a second side cover 620. The first side cover 610 and the second side cover 620 may be integrally formed. The first side cover 610 and the second side cover 620 may include, for example, metal.

The first side cover 610 may face a side surface of the display panel 10. The first side cover 610 may have a T-shaped cross section. The first side cover 610 may include a first cover 611 and a first support portion 612 that extend in different directions. The first cover 611 and the first support portion 612 may be integrally formed.

The first cover 611 may face a side surface of the display panel 10. The first cover 611 may extend in the third direction DR3.

The first support portion 612 may extend from an inner surface of the first cover 611. For example, the first support portion 612 may extend from the first cover 611 along the first direction DR1. For example, the first support portion 612 may be disposed below the first extension portion EX1 to support the first extension portion EX1. Specifically, the first support portion 612 may be disposed on the first extension portion EX1 such that the first extension portion EX1 is located between the display panel 10 and the first support portion 612. The first support portion 612 may be connected to the first cover 611 between upper and lower ends of the first cover 611.

The third adhesive member 81 may be disposed between the first support portion 612 and the first extension portion EX1. The third adhesive member 81 may bond the first support portion 612 and the first extension portion EX1 to each other.

The second side cover 620 may face the other side surface of the display panel 10. The second side cover 620 may have a T-shaped cross section. The second side cover 620 may include a second cover 621 and a second support portion 622. The second cover 621 and the second support portion 622 may be integrally formed.

The second cover 621 may face the other side surface of the display panel 10. The second cover 621 may extend in the third direction. Here, the “other side surface” of the display panel 10 may be, for example, a side surface of the display panel 10 that is adjacent to a pad portion of the substrate SUB or the driving board 30.

The second support portion 622 may extend from an inner surface of the second cover 621. For example, the second support portion 622 may extend from the second cover 621 in the first direction (reverse direction of the arrow in the coordinates). For example, the second support portion 622 may be disposed below the second extension portion EX2 to support the second extension portion EX2. Specifically, the second support portion 622 may be disposed on the second extension portion EX2 such that the second extension portion EX2 is located between the display panel 10 and the second support portion 622. The second support portion 622 may be connected to the second cover 621 between upper and lower ends of the second cover 621.

The fourth adhesive member 82 may be disposed between the second support portion 622 and the second extension portion EX2. The fourth adhesive member 82 may bond the second support portion 622 and the second extension portion EX2 to each other.

The side covers SCV of FIG. 11 may further include a third side cover and a fourth side cover instead of the third sidewall SW3 and the fourth sidewall SW4 of FIG. 1. The third side cover and the fourth side cover may have the same structure as the first side cover 610 described above. Here, the first side cover 610, the second side cover 620, the third side cover, and the fourth side cover may be integrally formed.

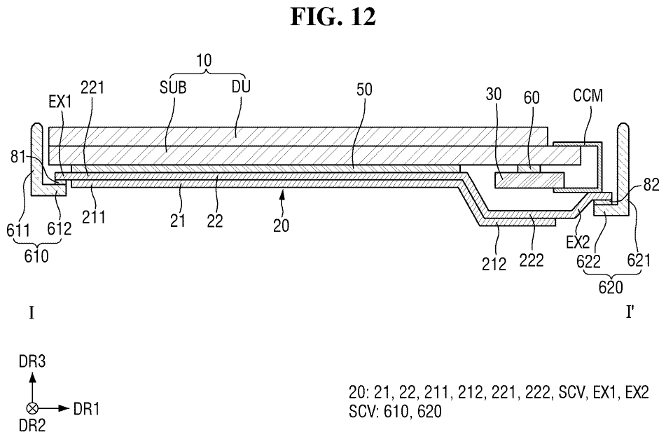

FIG. 12 is a cross-sectional view of a display device 1 according to an embodiment. For example, FIG. 12 may be a cross-sectional view taken along line I-I of FIG. 1.

The display device 1 of FIG. 12 is different from the display device of FIG. 11 in the shape of side covers SCV. In the interest of efficiency, the following description of the embodiment will focus on this difference.

As illustrated in FIG. 12, the side covers SCV may include a first side cover 610 and a second side cover 620. Similarly to the embodiment of FIG. 11, in the absence of sidewalls SW, the outward-facing surface of the vapor chamber 20 in FIG. 12 are part of the first and second extension portions EX1, EX2.

Each of the first side cover 610 and the second side cover 620 may have an L-shaped cross section. Here, the second side cover 620 may have a mirror-image of an L shape, so that the first side cover 610 and the second side cover 620 are symmetrical to each other with respect to an axis extending in the third direction DR3.

A first support portion 612 may extend (or protrude) from one end of a first cover 611 in the first direction DR1, giving the first side cover 610 and the second side cover 620 an L-shaped cross section and a mirror-image of L-shaped cross section, respectively.

A second support portion 622 may extend (or protrude) from a bottom end of a second cover 621 in the reverse first direction-DR1.

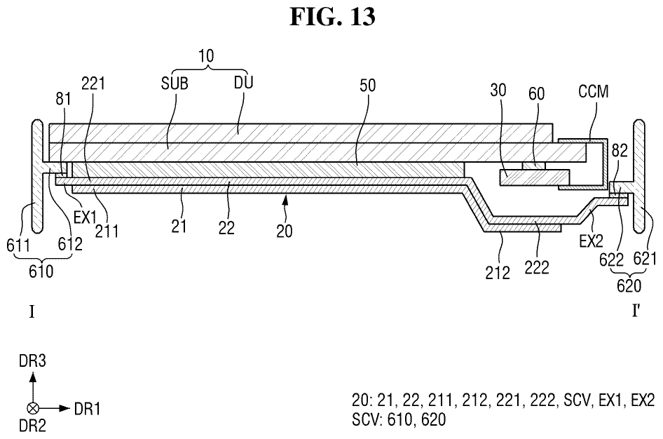

FIG. 13 is a cross-sectional view of a display device according to an embodiment. For example, FIG. 13 may be a cross-sectional view taken along line I-I of FIG. 1.

The display device of FIG. 13 is different from the display device of FIG. 11 in the positions of support portions of side covers SCV. Therefore, this difference will be mainly described as follows.

A first support portion 612 of a first side cover 610 of FIG. 13 may support a display panel 10. To this end, the first support portion 612 may be disposed between a vapor chamber 20 and the display panel 10. For example, the first support portion 612 may be disposed between a first extension portion EX1 of the vapor chamber 20 and a substrate SUB of the display panel 10. Similarly to the embodiments of FIG. 11 and FIG. 12, in the absence of sidewalls SW, the outward-facing surface of the vapor chamber 20 in FIG. 12 are the end parts of the first and second extension portions EX1, EX2.

A third adhesive member 81 may be disposed between the first extension portion EX1 and the first support portion 612. The third adhesive member 81 may bond the first extension portion EX1 and the first support portion 612 to each other.

A second support portion 622 of a second side cover 620 of FIG. 13 may be disposed on a second extension portion EX2. For example, the second support portion 622 may be disposed between the second extension portion EX2 and the substrate SUB of the display panel 10.

A fourth adhesive member 82 may be disposed between the second extension portion EX2 and the second support portion 622. The fourth adhesive member 82 may bond the second extension portion EX2 and the second support portion 622 to each other.

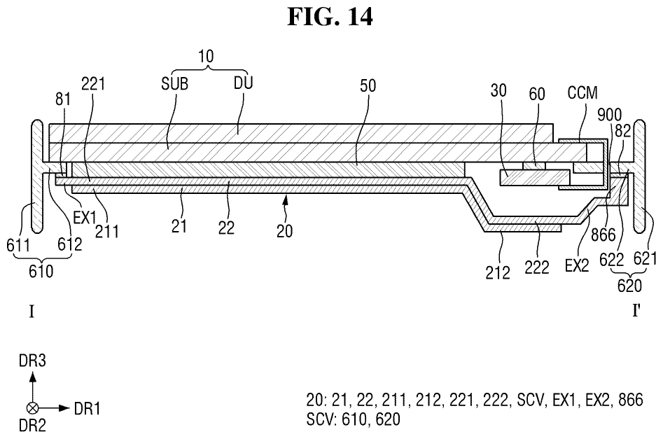

FIG. 14 is a cross-sectional view of a display device according to an embodiment. For example, FIG. 14 may be a cross-sectional view taken along line I-I of FIG. 1.

The display device of FIG. 14 is different from the display device of FIG. 13 in the positions of support portions of side covers SCV. Therefore, this difference will be mainly described as follows.

As illustrated in FIG. 14, a vapor chamber 20 may further include a protrusion 866 disposed on a second extension portion EX2. The protrusion 866 may extend from the second extension portion EX2 along the third direction DR3. The protrusion 866 may be integrally formed with the second extension portion EX2. The protrusion 866 may form the outward-facing surface of the vapor chamber 20 near the second side cover 620.

A second support portion 622 may be disposed between the protrusion 866 and a display panel 10. For example, the second support portion 622 may be disposed between the protrusion 866 and a substrate SUB of the display panel 10.

A fourth adhesive member 82 may be disposed between the protrusion 866 and the second support portion 622. The fourth adhesive member 82 may bond the protrusion 866 and the second support portion 622 to each other.

According to an embodiment, the second support portion 622 may have a through hole 900 passing therethrough. A circuit member CCM may pass through the through hole 900 of the second support portion 622. A pad portion of the substrate SUB and the circuit member CCM may be connected to each other through the through hole 900 of the second support portion 622.

The front cover 40 of FIG. 1 may be omitted. Where there is a front cover 40, a front cover extending along the second direction DR2 may be disposed on the display panel 10. Here, the front cover may be bar-shaped and disposed between the second sidewall SW2 and a side surface of the display layer DU.

According to a display device according to the present disclosure, a slim structure is possible, and manufacturing costs can be reduced.

However, the effects of the present disclosure are not restricted to the one set forth herein. The above and other effects of the present disclosure will become more apparent to one of daily skill in the art to which the present disclosure pertains by referencing the claims.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display panel having a side surface; and
a vapor chamber surrounding the side surface of the display panel.

2. The display device of claim 1, wherein the vapor chamber comprises a sidewall surrounding the side surface of the display panel.

3. The display device of claim 2, wherein the sidewall is integrally formed with the vapor chamber.

4. The display device of claim 2, wherein the display panel comprises a plurality of side surfaces, and the sidewall comprises a plurality of sidewalls facing the side surfaces.

5. The display device of claim 4, wherein at least one of the sidewalls contacts a side surface of the display panel.

6. The display device of claim 1, wherein the vapor chamber comprises:
a first plate;
a second plate between the first plate and the display panel;
an extension portion extending from an edge of the second plate; and
a sidewall disposed on the extension portion and surrounding the side surface of the display panel.

7. The display device of claim 6, wherein the second plate, the extension portion, and the sidewall are integrally formed.

8. The display device of claim 6, further comprising:
a first flange connected to an edge of the first plate; and
a second flange connected to the first flange and disposed on a portion of the second plate that is across the extension portion from the sidewall.

9. The display device of claim 6, wherein the first plate comprises a concave portion recessed toward the second plate.

10. The display device of claim 1, wherein the vapor chamber comprises:
a first plate;
a second plate between the first plate and the display panel;
an extension portion extending from an edge of the first plate; and
a sidewall disposed on the extension portion and surrounding the side surface of the display panel.

11. The display device of claim 10, wherein the first plate, the extension portion, and the sidewall are integrally formed.

12. The display device of claim 10, further comprising:
a second flange connected to an edge of the first plate; and
a first flange bonded to the second plate and disposed between the second flange and the extension portion.

13. The display device of claim 10, wherein the second plate comprises a concave portion recessed toward the first plate.

14. The display device of claim 1, further comprising a front cover on the display panel.

15. The display device of claim 14, wherein at least a portion of the vapor chamber further surrounds a side surface of the front cover.

16. The display device of claim 15, wherein the vapor chamber comprises a sidewall surrounding the side surface of the display panel and the side surface of the front cover.

17. A display device comprising:
a display panel having a side surface;
a vapor chamber having a bottom plate connected to an outward-facing surface; and
a side cover surrounding a side surface of the display panel and the outward-facing surface of the vapor chamber.

18. The display device of claim 17, wherein the side cover comprises:
a support portion extending from an inner surface of the side cover.

19. The display device of claim 18, wherein the support portion is disposed below the vapor chamber.

20. The display device of claim 18, wherein the support portion is disposed between the vapor chamber and the display panel.

21. The display device of claim 18, further comprising a circuit member connected to the display panel, wherein the support portion has a through hole through which the circuit member extends.
